(19) United States
(12) Patent Application Publication
(10) Pub. No.: US 2026/0222079 A1
(43) Pub. Date: Jul. 30, 2026

(54) OPTICAL DETECTION DEVICE AND TRANSCEIVER DEVICE

(71) Applicant: TDK Corporation, Tokyo (JP)

(72) Inventors: Weihao ZHANG, Tokyo (JP); Tetsuya SHIBATA, Tokyo (JP); Yusho HIRATA, Tokyo (JP); Hideaki FUKUZAWA, Tokyo (JP)

(73) Assignee: TDK Corporation, Tokyo (JP)

(21) Appl. No.: 19/443,246

(22) Filed: Jan. 8, 2026

(30) Foreign Application Priority Data
Jan. 24, 2025 (JP) 2025-010521

(51) Int. Cl. H04B 10/69; H03F 1/34; H04B 10/40; H04B 10/50

(52) U.S. Cl. CPC H04B 10/697; H03F 1/34; H04B 10/40; H04B 10/505

(57) ABSTRACT

The optical detection device 100 comprises a first magnetic element 10, a second magnetic element 20, and a differential synthesis circuit 30. The first magnetic element comprises a first ferromagnetic layer 11, a second ferromagnetic layer 12, and a first spacer layer 13, and generates a first voltage signal when the first ferromagnetic layer is irradiated with light containing an optical signal. The second magnetic element comprises a third ferromagnetic layer 21, a fourth ferromagnetic layer 22, and a second spacer layer 23 sandwiched between the third and fourth ferromagnetic layers, and generates a second voltage signal of opposite phase to the first voltage signal when the same light is simultaneously irradiated to the third ferromagnetic layer. The differential synthesis circuit differentially synthesizes a first total voltage signal output from the first magnetic element and a second total voltage signal output from the second magnetic element.

### CROSS-REFERENCE TO RELATED APPLICATION

This application claims a priority, under the Paris Convention, to Japanese Patent Application No. 2025-010521 filed on Jan. 24, 2025, the entirety of which is incorporated herein by reference.

### TECHNICAL FIELD

The present disclosure relates to an optical detection device and a transceiver device.

### BACKGROUND

Optical detection devices using photoelectric conversion elements are used for various applications. For example, Japanese Patent Application Publication No. 2001-292107describes a reception device that receives an optical signal using a photodiode. The photodiode is, for example, a pn junction diode using a semiconductor pn junction, and converts light into an electrical signal. For example, Japanese Patent Application Publication No.2022-69387 (JP 2022-69387 A) discloses an optical sensor using a magnetic element that can extract light as an electrical signal, and a reception device using this optical sensor. For example, Japanese Patent Application Publication No. H10-221164 discloses a laser sensor device that detects laser light as an electrical signal, and describes the use of a differential circuit to remove the effects of noise light.

FIG. 14 is a diagram showing the configuration of a conventional optical detection device 1000 described in, for example, JP 2022-69387 A. As shown in FIG. 14, the magnetic element 110 of the conventional optical detection device 1000 includes a first ferromagnetic layer 111 as a magnetization (M1) free layer, a second ferromagnetic layer 112 as a magnetization (M2) fixed layer, and a spacer layer 113. The spacer layer 113 is sandwiched between the first ferromagnetic layer 111 and the second ferromagnetic layer 112, which form a laminate. The conventional optical detection device 1000 further includes a first electrode 114 and a second electrode 115 sandwiching the laminate in the stacking direction (z-axis direction). A bias current IB is caused to flow through the magnetic element 110 by an external constant current source connected to the first electrode 114 and the second electrode 115. An output terminal is connected to the first electrode 114.

FIG. 15A shows the time waveform of the output signal V_{OUT} output from the output terminal when the magnetic element 110 is irradiated with light Ls having an optical signal in the conventional optical detection device 1000 of FIG. 14, and FIG. 15B shows the time waveform of the noise signal V_{NOISE} output from the first electrode 114. The optical signal is assumed to have an optical intensity that fluctuates at a predetermined frequency. When the conventional optical detection device 1000 is irradiated with light Ls having an optical signal, a real (voltage) signal V_{REAL} that actually corresponds to the optical signal is output from the first electrode 114. Also, as shown in FIG. 15B, a noise signal V_{NOISE} generated by irradiation of light Ls having an optical signal is also output from the first electrode 114. That is, the output signal V_{OUT} of FIG. 15A output from the output terminal is the real signal V_{REAL} plus the noise signal V_{NOISE}. This means V_{OUT}=V_{REAL}+V_{NOISE}. However, as recognized by the present inventors, it was found that the noise signal V_{NOISE} has a certain phase difference with respect to the real signal V_{REAL}. Therefore, the output signal V_{OUT} was distorted. For example, there was a problem that the peak-to-peak value of the real signal V_{REAL} changes or decreases due to the noise signal V_{NOISE} having a phase difference.

One aspect of the present disclosure has been made in consideration of the above problems, and aims to provide an optical detection device and a transceiver device that can remove a phase-shifted noise signal generated when light having an optical signal is irradiated to a magnetic element.

### SUMMARY

One aspect of the present disclosure provides an optical detection device comprises a first magnetic element including a first ferromagnetic layer, a second ferromagnetic layer, and a first spacer layer sandwiched between the first ferromagnetic layer and the second ferromagnetic layer, wherein when the first ferromagnetic layer is irradiated with light including an optical signal, the first magnetic element generates a first voltage signal in response to the optical signal, a second magnetic element including a third ferromagnetic layer, a fourth ferromagnetic layer, and a second spacer layer sandwiched between the third ferromagnetic layer and the fourth ferromagnetic layer, wherein when the third ferromagnetic layer is simultaneously irradiated with the light, the second magnetic element generates a second voltage signal in opposite phase to the first voltage signal corresponding to the optical signal, and a differential synthesis circuit that differentially synthesizes a first total voltage signal including the first voltage signal output from the first magnetic element and a second total voltage signal including the second voltage signal output from the second magnetic element including the second voltage signal.

In another aspect, the present disclosure provides a transceiver device comprises a transmission device having a light source that emits light with a wavelength of 400 nm or more and 1500 nm or less, modulating and outputting the emitted light, and a reception device having any of the above-mentioned optical detection devices that detect light with a wavelength of 400 nm or more and 1500 nm or less, demodulating the detected light.

### BRIEF DESCRIPTION OF DRAWINGS

FIG. 1 shows a diagram showing the basic configuration of an optical detection device according to an embodiment of the present disclosure.

FIG. 2 shows a diagram showing the general configuration of an optical detection device according to a first embodiment of the present disclosure.

FIG. 3A shows the time waveform of a first total voltage signal output from a first magnetic element.

FIG. 3B shows the time waveform of a second total voltage signal output from a second magnetic element.

FIG. 3C shows the time waveform of an output signal output from a differential synthesis circuit.

FIG. 4 shows a diagram showing the general configuration of an optical detection device according to a second embodiment of the present disclosure.

FIG. 5A shows the time waveform of a first total voltage signal output from a first magnetic element.

FIG. 5B shows the time waveform of a second total voltage signal output from a second magnetic element.

FIG. 5C shows the time waveform of an output signal output from a differential synthesis circuit.

FIG. 6 shows a diagram showing the general configuration of an optical detection device according to a third embodiment of the present disclosure.

FIG. 7 shows a diagram showing the general configuration of an optical detection device according to a fourth embodiment of the present disclosure.

FIG. 8 shows a diagram showing the time waveforms of each signal in a differential synthesis circuit.

FIG. 9 shows a diagram showing the general configuration of an optical detection device according to a fifth embodiment of the present disclosure.

FIG. 10 shows a diagram showing the time waveforms of each signal in a differential synthesis circuit.

FIG. 11 shows a diagram showing the configuration of a transceiver device according to an embodiment of the present disclosure.

FIG. 12 shows a diagram showing the configuration of a communication system according to an embodiment of the present disclosure.

FIG. 13 shows a diagram showing the configuration of a terminal device according to an embodiment of the present disclosure.

FIG. 14 shows a diagram showing the configuration of a conventional optical detection device.

FIG. 15A shows the time waveform of the total voltage signal (output signal) output from the magnetic element in the conventional optical detection device of FIG. 14.

FIG. 15B shows the time waveform of the noise signal output from the magnetic element.

### DETAILED DESCRIPTION

Hereinafter, an embodiment of the present disclosure will be described in detail with reference to the drawings. It should be noted that to facilitate understanding, the scale of each part in the drawings may differ from the actual scale. In the xyz Cartesian coordinate system set in the figure, the x-axis and y-axis directions are horizontal, and the z-axis direction is vertical. The positive z-axis direction is also called the upward direction, and the negative z-axis direction is also called the downward direction, but this has nothing to do with the direction of gravity. In the directions of parallel, right-angled, orthogonal, horizontal, vertical, up-down, left-right, etc., deviations that do not impair the effect of the embodiment are permitted. In addition, “to” indicating a numerical range means that the numerical values before and after it are included as the lower and upper limits.

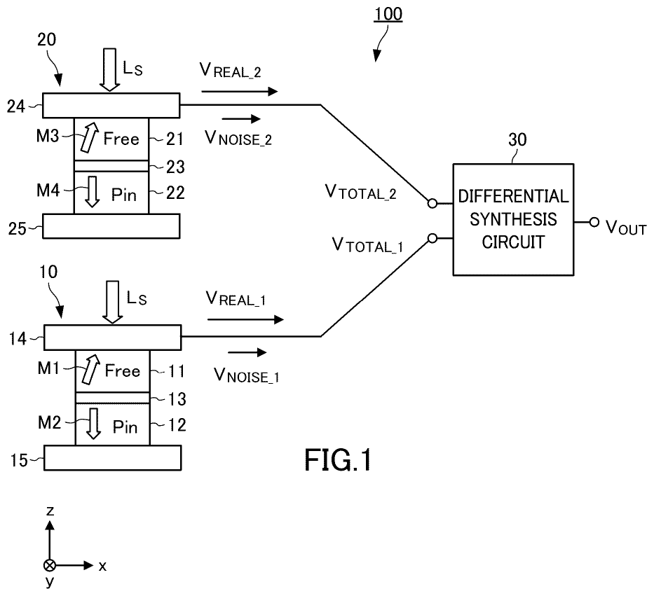

FIG. 1 is a diagram showing the basic configuration of an optical detection device 100 according to an embodiment of the present disclosure. As shown in FIG. 1, the optical detection device 100 includes a first magnetic element 10, a second magnetic element 20, and a differential synthesis circuit 30.

The first magnetic element 10 includes a first ferromagnetic layer 11, a second ferromagnetic layer 12, and a first spacer layer 13 sandwiched between the first ferromagnetic layer 11 and the second ferromagnetic layer 12. The first magnetic element 10 further includes a first electrode 14 provided on the side of the first ferromagnetic layer 11 opposite to the first spacer layer 13, and a second electrode 15 provided on the side of the second ferromagnetic layer 12 opposite to the first spacer layer 13. The first electrode 14 is a transparent electrode that transmits light. This makes it possible to allow the light incident on the first magnetic element 10 to be irradiated to the first ferromagnetic layer 11 with almost no attenuation. When light Ls including an optical signal is irradiated to the first ferromagnetic layer 11, the first magnetic element 10 generates a first voltage signal (hereinafter also referred to as a first real signal) V_{REAL_1} corresponding to the optical signal, and generates a first noise signal V_{NOISE_1} that is out of phase with the first real signal V_{REAL_1}.

The second magnetic element 20 comprises a third ferromagnetic layer 21, a fourth ferromagnetic layer 22, and a second spacer layer 23 sandwiched between the third ferromagnetic layer 21 and the fourth ferromagnetic layer 22. The second magnetic element 20 further comprises a third electrode 24 provided on the side of the third ferromagnetic layer 21 opposite the second spacer layer 23, and a fourth electrode 25 provided on the side of the fourth ferromagnetic layer 22 opposite the second spacer layer 23. The third electrode 24 is a transparent electrode that transmits light. This make it possible to allow the light incident on the second magnetic element 20 to be irradiated to the third ferromagnetic layer 21 with almost no attenuation. When the third ferromagnetic layer 21 is simultaneously irradiated with the same light as that incident on the first ferromagnetic layer 11, the second magnetic element 20 generates a second voltage signal (hereinafter also referred to as a second real signal) V_{REAL_2} in opposite phase to the first voltage signal in response to the same light signal, and generates a second noise signal V_{NOISE_2} out of phase with the second real signal V_{REAL_2}.

The sum of the first real signal V_{REAL_1} and the first noise signal V_{NOISE_1} output from the first magnetic element 10 is the first total voltage signal V_{TOTAL_1}, which is the total sum of the output voltages. In other words, the first total voltage signal V_{TOTAL_1} is composed of a first real signal V_{REAL_1} (e.g., an electrical modulation signal) corresponding to an optical signal (e.g., an optical modulation signal) included in the irradiated light, and a first noise signal V_{NOISE_1} out of phase with the first real signal V_{REAL_1}. Similarly, the sum of the second real signal V_{REAL_2} and the second noise signal V_{NOISE_2} output from the second magnetic element 20 is the second total voltage signal V_{TOTAL_2}, which is the total sum of the output voltages. In other words, the second total voltage signal V_{TOTAL_2} is made up of a second real signal V_{REAL_2} (e.g., an electrical modulation signal) corresponding to an optical signal (e.g., an optical modulation signal) contained in the irradiated light, and a second noise signal V_{NOISE_2} that is out of phase with respect to the second real signal V_{REAL_2}. The first real signal V_{REAL_1} and the second real signal V_{REAL_2} are in opposite phase, and the first noise signal V_{NOISE_1} and the second noise signal V_{NOISE_2} are in phase.

The differential synthesis circuit 30 is adapted to differentially synthesize the first total voltage signal V_{TOTAL_1}, which is output from the first magnetic element 10 including the first real signal V_{REAL_1}, and the second total voltage signal V_{TOTAL_2}, which is output from the second magnetic element 20 including the second real signal V_{REAL_2}. Specifically, the differential synthesis circuit 30 outputs the difference between the first total voltage signal V_{TOTAL_1} and the second total voltage signal V_{TOTAL_2}.

When the two identical waveform signals input to the differential synthesis circuit 30 are in phase, the two identical waveform signals are cancelled out by the differential synthesis, so that the output signal becomes zero. On the other hand, when the two identical waveform signals input to the differential synthesis circuit 30 are in opposite phase (phase difference is 180°), the output signal becomes twice as large as the single input signal due to the differential synthesis.

The “light” described in this specification is not limited to visible light, but may be infrared light, which has a longer wavelength than visible light, or ultraviolet light, which has a shorter wavelength than visible light. For example, it may be light with a wavelength of 400 nm or more and 1500 nm or less. The wavelength of visible light is, for example, 380 nm or more and less than 800 nm. The wavelength of infrared light is, for example, 800 nm or more and 1 mm or less. The wavelength of ultraviolet light is, for example, 200 nm or more and less than 380 nm.

Each component will be described hereinafter.

As shown in FIG. 1, the first magnetic element 10 is a laminate formed by stacking at least the first electrode 14, the first ferromagnetic layer 11, the first spacer layer 13, the second ferromagnetic layer 12, and the second electrode 15 in this order in the z-axis direction. Similarly, the second magnetic element 20 is a laminate formed by stacking at least a third electrode 24, a third ferromagnetic layer 21, a second spacer layer 23, a fourth ferromagnetic layer 22, and a fourth electrode 25 in this order in the z-axis direction. The first magnetic element 10 and the second magnetic element 20 may include layers other than those mentioned above as necessary.

The first magnetic element 10 and the second magnetic element 20 have the same configuration and size, and are arranged adjacent to each other within the spot of the incident light Ls. The first magnetic element 10 and the second magnetic element 20 are simultaneously subjected to the same incident light Ls including an optical signal such as an optical modulation signal. Since the first magnetic element 10 and the second magnetic element 20 have the same configuration, the configuration of only the first magnetic element 10 will be described hereinafter, but the same description can be applied to the second magnetic element 20.

The first magnetic element 10 is, for example, a magnetic tunnel junction (MTJ) element in which the first spacer layer 13 is made of an insulating material. In this case, the first magnetic element 10 can exhibit a tunnel magnetoresistance (TMR: Tunnel Magneto Resistance) effect. The resistance value of the first magnetic element 10 changes when the first magnetic element 10 is irradiated with light from the outside. The resistance value of the first magnetic element 10 in the z-axis direction (resistance value when a current is passed in the z-axis direction) changes in response to the relative change between the state of magnetization M1 of the first ferromagnetic layer 11 and the state of magnetization M2 of the second ferromagnetic layer 12. For example, the resistance value of the first magnetic element 10 in the z-axis direction changes in response to the change in the relative angle between the direction of magnetization M1 of the first ferromagnetic layer 11 and the direction of magnetization M2 of the second ferromagnetic layer 12. Also, for example, the resistance value of the first magnetic element 10 in the z-axis direction changes in response to the change in the magnitude of magnetization M1 of the first ferromagnetic layer 11.

For example, when the first spacer layer 13 is made of a metal, the first magnetic element 10 can exhibit a giant magnetoresistance (GMR) effect. Such an element is called a GMR element. When the first magnetic element 10 is a GMR element, the resistance value in the z-axis direction (resistance value when a current is passed in the z-axis direction) changes in response to the relative change between the state of magnetization M1 of the first ferromagnetic layer 11 and the state of magnetization M2 of the second ferromagnetic layer 12. The first magnetic element 10 may be called an MTJ element, a GMR element, or the like, different in name depending on the material of the first spacer layer 13, but is collectively called a magnetoresistance effect element. The total thickness of the first magnetic element 10 is, for example, 15 nm to 40 nm.

The first magnetic element 10 may have a ferromagnetic material whose magnetization state changes when irradiated with light, and the resistance value may change with the change in the magnetization state. The first magnetic element 10 may be, for example, an anisotropic magnetoresistance (AMR) effect element, a colossal magnetoresistance (CMR) effect element, or the like, in addition to the above-mentioned MTJ element and GMR element.

The first ferromagnetic layer 11 is a light detection layer in which the state of magnetization M1 changes when light Ls is irradiated from the outside. The first ferromagnetic layer 11 is also called a magnetization free layer. The magnetization free layer is a layer containing a magnetic material in which the state of magnetization M1 changes when a predetermined external energy is applied. The predetermined external energy is, for example, light irradiated from the outside, a current flowing in the z-axis direction of the first magnetic element 10, an external magnetic field, or the like. The state of magnetization M1 of the first ferromagnetic layer 11 changes depending on the intensity of the irradiated light.

The first ferromagnetic layer 11 includes a ferromagnetic material. The first ferromagnetic layer 11 includes at least one of magnetic elements such as Co, Fe, or Ni. The first ferromagnetic layer 11 may include elements such as B, Mg, Hf, and Gd in addition to the magnetic elements described above. The first ferromagnetic layer 11 may be, for example, an alloy including a magnetic element and a nonmagnetic element. The first ferromagnetic layer 11 may be composed of multiple layers. The first ferromagnetic layer 11 may be, for example, a CoFeB alloy, a laminate in which a CoFeB alloy layer is sandwiched between Fe layers, or a laminate in which a CoFeB alloy layer is sandwiched between CoFe layers. In general, “ferromagnetic” includes “ferrimagnetic”. The first ferromagnetic layer 11 may exhibit ferrimagnetic properties. Alternatively, the first ferromagnetic layer 11 may exhibit ferromagnetic properties that are not ferrimagnetic. For example, a CoFeB alloy exhibits ferromagnetic properties that are not ferrimagnetic.

The first ferromagnetic layer 11 may be an in-plane magnetized film having an axis of easy magnetization in the in-plane direction (any direction in the xy plane) or a perpendicular magnetized film having an axis of easy magnetization in the direction perpendicular to the film plane (z-axis direction).

The film thickness of the first ferromagnetic layer 11 is, for example, 1 nm to 5 nm. The film thickness of the first ferromagnetic layer 11 is preferably, for example, 1 nm to 2 nm. When the first ferromagnetic layer 11 is a perpendicular magnetized film, if the film thickness of the first ferromagnetic layer 11 is thin, the effect of applying perpendicular magnetic anisotropy from the layers above and below the first ferromagnetic layer 11 is strengthened, and the perpendicular magnetic anisotropy of the first ferromagnetic layer 11 is enhanced. In other words, if the perpendicular magnetic anisotropy of the first ferromagnetic layer 11 is high, the force that causes the magnetization M1 to return to the z-axis direction is strengthened. On the other hand, if the thickness of the first ferromagnetic layer 11 is large, the effect of applying perpendicular magnetic anisotropy from the layers above and below the first ferromagnetic layer 11 is relatively weakened, and the perpendicular magnetic anisotropy of the first ferromagnetic layer 11 is weakened.

If the thickness of the first ferromagnetic layer 11 is thin, the volume of the ferromagnetic body is small, and if the thickness is thick, the volume of the ferromagnetic body is large. The responsiveness of the magnetization M1 of the first ferromagnetic layer 11 when external energy is applied is inversely proportional to the product (KuV) of the magnetic anisotropy (Ku) and the volume (V) of the first ferromagnetic layer 11. In other words, if the product of the magnetic anisotropy and the volume of the first ferromagnetic layer 11 is small, the responsiveness to light is increased. From this perspective, in order to increase the responsiveness to light, it is preferable to appropriately design the magnetic anisotropy of the first ferromagnetic layer 11 and then reduce the volume of the first ferromagnetic layer 11.

If the thickness of the first ferromagnetic layer 11 is greater than 2 nm, an insertion layer made of, for example, Mo or W may be provided within the first ferromagnetic layer 11. In other words, the first ferromagnetic layer 11 may be a laminate in which a ferromagnetic layer, an insertion layer, and a ferromagnetic layer are stacked in this order in the z-axis direction. The interfacial magnetic anisotropy at the interface between the insertion layer and the ferromagnetic layer increases the perpendicular magnetic anisotropy of the entire first ferromagnetic layer 11. The thickness of the insertion layer is, for example, 0.1 nm to 1.0 nm.

The second ferromagnetic layer 12 is a magnetization fixed (pinned) layer. The magnetization fixed layer is a layer made of a magnetic material in which the state of magnetization M2 is less likely to change than the magnetization free layer when a predetermined external energy is applied. For example, the magnetization fixed layer is less likely to change the direction of magnetization M2 than the magnetization free layer when a predetermined external energy is applied. Also, for example, the magnetization fixed layer is less likely to change the magnitude of magnetization M2 than the magnetization free layer when a predetermined external energy is applied. The coercive force of the second ferromagnetic layer 12 is, for example, greater than the coercive force of the first ferromagnetic layer 11. The second ferromagnetic layer 12 has an easy magnetization axis in the same direction as the first ferromagnetic layer 11. The second ferromagnetic layer 12 may be an in-plane magnetized film or a perpendicular magnetized film.

The material constituting the second ferromagnetic layer 12 is, for example, the same as that of the first ferromagnetic layer 11. The second ferromagnetic layer 12 may be, for example, a multilayer film in which Co having a thickness of 0.4 nm to 1.0 nm and Pt having a thickness of 0.4 nm to 1.0 nm are alternately stacked several times. The second ferromagnetic layer 12 may be, for example, a laminate in which Co having a thickness of 0.4 nm to 1.0 nm, Mo having a thickness of 0.1 nm to 0.5 nm, CoFeB alloy having a thickness of 0.3 nm to 1.0 nm, and Fe having a thickness of 0.3 nm to 1.0 nm are stacked in this order.

The first spacer layer 13 is a layer disposed between the first ferromagnetic layer 11 and the second ferromagnetic layer 12. The first spacer layer 13 is a layer made of a conductor, an insulator, or a semiconductor, or a layer containing a current-carrying point made of a conductor in an insulator. The first spacer layer 13 is, for example, a nonmagnetic layer. The thickness of the first spacer layer 13 can be adjusted depending on the orientation of the magnetization M1 of the first ferromagnetic layer 11 and the magnetization M2 of the second ferromagnetic layer 12 in the initial state described later.

When the first spacer layer 13 is made of an insulating material, a material containing aluminum oxide, magnesium oxide, titanium oxide, silicon oxide, or the like can be used as the material of the first spacer layer 13. These insulating materials may also contain elements such as Al, B, Si, and Mg, or magnetic elements such as Co, Fe, and Ni. By adjusting the thickness of the first spacer layer 13 so that a high TMR effect is generated between the first ferromagnetic layer 11 and the second ferromagnetic layer 12, a high magnetoresistance change rate can be obtained. In order to efficiently utilize the TMR effect, the thickness of the first spacer layer 13 may be about 0.5 nm to 5.0 nm, or about 1.0 nm to 2.5 nm.

When the first spacer layer 13 is made of a non-magnetic conductive material, conductive materials such as Cu, Ag, Au, or Ru can be used. In order to efficiently utilize the GMR effect, the film thickness of the first spacer layer 13 may be about 0.5 nm to 5.0 nm, or about 2.0 nm to 3.0 nm.

When the first spacer layer 13 is made of a non-magnetic semiconductor material, materials such as zinc oxide, indium oxide, tin oxide, germanium oxide, gallium oxide, or indium tin oxide (ITO) can be used. In this case, the film thickness of the first spacer layer 13 may be about 1.0 nm to 4.0 nm.

When a layer including a current-carrying point formed by a conductor in a non-magnetic insulator is used as the first spacer layer 13, a structure including a current-carrying point formed by a non-magnetic conductor such as Cu, Au, or Al in a non-magnetic insulator made of aluminum oxide or magnesium oxide may be used. The conductor may also be made of magnetic elements such as Co, Fe, and Ni. In this case, the film thickness of the first spacer layer 13 may be about 1.0 nm to 2.5 nm. The current-carrying point is, for example, a columnar body with a diameter of 1.0 nm to 5.0 nm when viewed from a direction perpendicular to the film surface.

The first electrode 14 is, for example, disposed on the opposite side of the first ferromagnetic layer 11 from the first spacer layer 13 side. Incident light Ls is irradiated from the first electrode 14 side to the first magnetic element 10, and is irradiated at least to the first ferromagnetic layer 11. The first electrode 14 is made of a material having electrical conductivity. The first electrode 14 is, for example, a transparent electrode that is transparent to light in the wavelength range used. It is preferable that the first electrode 14 transmits, for example, 80% or more of light in the wavelength range used. The first electrode 14 is, for example, an oxide such as indium tin oxide (ITO), indium zinc oxide (IZO), zinc oxide (ZnO), or indium gallium zinc oxide (IGZO). The first electrode 14 may be configured to have a plurality of metal columns in a transparent electrode material of these oxides.

It is not essential to use the above-mentioned transparent electrode material for the first electrode 14, and a metal material such as Au, Cu, or Al may be used with a thin film thickness to allow the irradiated light to reach the first ferromagnetic layer 11. When a metal is used as the material for the first electrode 14, the film thickness of the first electrode 14 is, for example, 3 nm to 10 nm. The first electrode 14 may also have an anti-reflection film on the irradiation surface to which light is irradiated.

The second electrode 15 is made of a material having electrical conductivity. The second electrode 15 is made of, for example, a metal such as Cu, Al, or Au. Ta or Ti may be laminated above and below these metals. A laminated film of Cu and Ta, a laminated film of Ta, Cu and Ti, or a laminated film of Ta, Cu and TaN may also be used. TiN or TaN may also be used as the second electrode 15. The film thickness of the second electrode 15 is, for example, 200 nm to 800 nm.

The second electrode 15 may be transparent to the light irradiated to the first magnetic element 10. Similarly to the first electrode 14, the second electrode 15 may be made of a transparent electrode material such as indium tin oxide (ITO), indium zinc oxide (IZO), zinc oxide (ZnO), indium gallium zinc oxide (IGZO), or other oxide. Even when light is irradiated from the first electrode 14, the light may reach the second electrode 15 depending on the intensity of the light. In this case, the second electrode 15 made of a transparent electrode material of oxide can suppress the reflection of light at the interface between the second electrode 15 and the layer in contact therewith, as compared with the case where the second electrode 15 is made of a metal.

The first ferromagnetic layer 11, the second ferromagnetic layer 12, the first spacer layer 13, the first electrode 14, and the second electrode 15 of the first magnetic element 10 have been described hereinbefore, but the second magnetic element 20 having the same structure as that of the first magnetic element 10 should be understood as the same way as that of the first magnetic element 10. The first ferromagnetic layer 11, the second ferromagnetic layer 12, the first spacer layer 13, the first electrode 14, and the second electrode 15 of the first magnetic element 10 correspond to the third ferromagnetic layer 21, the fourth ferromagnetic layer 22, the second spacer layer 23, the third electrode 24, and the fourth electrode 25 of the second magnetic element 20, respectively.

The first magnetic element 10 and the second magnetic element 20 are fabricated, for example, by a lamination process, an annealing process, and a processing process for each layer. Each layer is formed, for example, by sputtering. Annealing is performed, for example, at 250° C. or higher and 450° C. or lower. The laminated film is processed, for example, by photolithography and etching. The shortest width of each of the first magnetic element 10 and the second magnetic element 20 when viewed from the z direction may be, for example, 10 nm or higher and 2000 nm or lower, or 30 nm or higher and 500 nm or lower.

Next, the operation of the optical detection device 100 will be explained.

The light Ls incident on the optical detection device 100 is focused, for example, by a lens to form a light spot that is irradiated simultaneously to the first magnetic element 10 and the second magnetic element 20. Since the first magnetic element 10 and the second magnetic element 20 have the same structure, the operation of the first magnetic element 10 will be described hereinafter.

When the intensity of the light Ls irradiated to the first ferromagnetic layer 11 changes, the state of the magnetization M1 of the first ferromagnetic layer 11 changes. The state of the magnetization M1 refers to, for example, the inclination angle of the magnetization M1 with respect to the z-axis direction, the magnitude of the magnetization M1, etc.

For example, when the intensity of the light Ls irradiated to the first ferromagnetic layer 11 increases, the magnetization M1 of the first ferromagnetic layer 11 tilts from its initial state due to external energy caused by the light irradiation. The angle between the direction of the magnetization M1 of the first ferromagnetic layer 11 in a state where the first ferromagnetic layer 11 is not irradiated with light Ls (hereinafter referred to as the initial state) and the direction of the magnetization M1 in a state where the light is irradiated is, for example, greater than 0° and smaller than 90°. Alternatively, for example, when the intensity of the light irradiated to the first ferromagnetic layer 11 increases, the magnitude of the magnetization M1 decreases.

When the state of the magnetization M1 of the first ferromagnetic layer 11 changes, the resistance value in the z-axis direction of the first magnetic element 10 changes due to the magnetoresistance effect. When a constant current (called a sense current or a bias current) is passed through the first magnetic element 10 in the positive or negative direction of the z-axis using the first electrode 14 and the second electrode 15, an output voltage is obtained from the first magnetic element 10. That is, when the state of the magnetization M1 of the first ferromagnetic layer 11 changes, the output voltage from the first magnetic element 10 also changes.

In the initial state of the first ferromagnetic layer 11, the magnetization M1 of the first ferromagnetic layer 11 and the magnetization M2 of the second ferromagnetic layer 12 may be in parallel or antiparallel relationship, or the magnetization M1 and the magnetization M2 may be perpendicular to each other.

In the optical detection device 100 shown in FIG. 1, the first magnetic element 10 and the second magnetic element 20, which have the same physical structure, are connected to a differential synthesis circuit 30. In this configuration, when the first magnetic element 10 and the second magnetic element 20 are simultaneously irradiated with light Ls having the same optical signal, the first noise signal V_{NOISE_1} and the second noise signal V_{NOISE_2} have the same phase and amplitude, so that they cancel each other to zero in the differential synthesis circuit 30, and the influence of the noise signals can be suppressed. In addition, by setting the first real signal V_{REAL_1} and the second real signal V_{REAL_2} so that the phase difference between the first magnetic element 10 and the second magnetic element 20 is 180°, the peak-to-peak value of the output voltage can be increased in the differential synthesis circuit 30.

More specifically, in FIG. 1, the first total voltage signal V_{TOTAL_1} and the second total voltage signal V_{TOTAL_2} are expressed by the following equations.

V_{TOTAL_1}=V_{REAL_1}+V_{NOISE_1}

V_{TOTAL_2}=V_{REAL_2}+V_{NOISE_2}

Furthermore, the first noise signal V_{NOISE_1} and the second noise signal V_{NOISE_2} are

V_{NOISE_1}=V_{NOISE_2}

and therefore, the output signal V_{OUT} is

V_{OUT}=V_{TOTAL_1}−V_{TOTAL_2}=(V_{REAL_1}+V_{NOISE_1})−(V_{REAL_2}+V_{NOISE_2})=V_{REAL_1}−V_{REAL_2}.

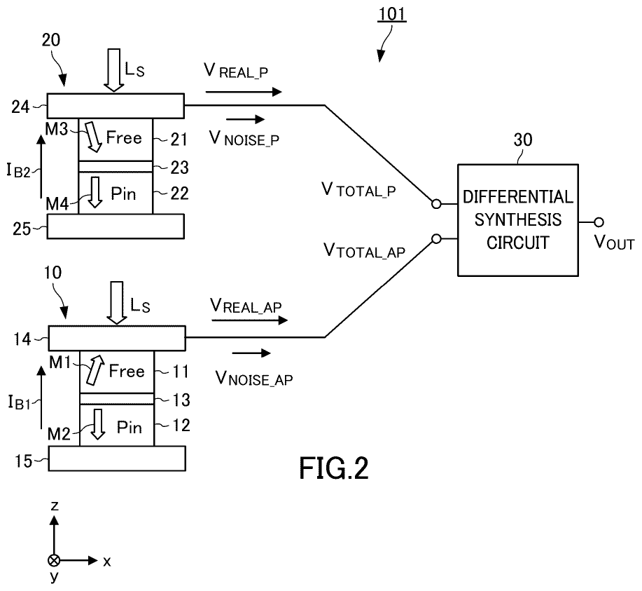

A first embodiment of the present disclosure will be described. FIG. 2 is a diagram showing a schematic configuration of an optical detection device 101 according to a first embodiment of the present disclosure. The first embodiment differs from the above basic configuration in that the magnetization states of the first magnetic element 10 and the second magnetic element 20 are specified. The other configuration is the same as the basic configuration described above, and the same components are given the same reference numerals, and the descriptions are omitted.

As shown in FIG. 2, in the optical detection device 101, the magnetization directions of the first ferromagnetic layer 11 and the second ferromagnetic layer 12 of the first magnetic element 10 are antiparallel (AP), and the magnetization directions of the third ferromagnetic layer 21 and the fourth ferromagnetic layer 22 of the second magnetic element 20 are parallel (P). That is, the first magnetic element 10 is set to an antiparallel magnetization state, and the second magnetic element 20 is set to a parallel magnetization state.

The bias current (also called the sense current) IB1 applied from the outside to the first magnetic element 10 flows in the positive direction of the z-axis from the second electrode 15 through the second ferromagnetic layer 12, the first spacer layer 13, and the first ferromagnetic layer 11 to the first electrode 14. That is, in the first magnetic element 10, the bias current IB1 flows from the pinned layer (second ferromagnetic layer 12) to the free layer (first ferromagnetic layer 11). The bias current IB2 applied from the outside to the second magnetic element 20 flows from the fourth electrode 25 through the fourth ferromagnetic layer 22, the second spacer layer 23, and the third ferromagnetic layer 21 to the third electrode 24. That is, in the second magnetic element 20, the bias current IB2 flows from the pinned layer (fourth ferromagnetic layer 22) to the free layer (third ferromagnetic layer 21) in the same way as that in the first magnetic element 10.

Alternatively, in the first magnetic element 10, a bias current IB1 may be caused to flow from the free layer (first ferromagnetic layer 11) to the pinned layer (second ferromagnetic layer 12), and in the second magnetic element 20, a bias current IB2 may be caused to flow from the free layer (third ferromagnetic layer 21) to the pinned layer (fourth ferromagnetic layer 22), similarly to the first magnetic element 10.

With this configuration, the first real signal V_{REAL_AP} output from the first magnetic element 10 and the second real signal V_{REAL_P} output from the second magnetic element 20 can be made to have opposite phases (phase difference of 180°).

In the differential synthesis circuit 30, the first noise signal V_{NOISE_AP} and the second noise signal V_{NOISE_P}, which are in phase, cancel each other, and the first real signal V_{REAL_AP} and the second real signal V_{REAL_P}, which are in opposite phase, are substantially added together. The second real signal V_{REAL_P} output from the second magnetic element 20 in the parallel magnetization state is almost zero, and the majority of the second total voltage signal V_{TOTAL_P} is the second noise signal V_{NOISE_P}.

In more detail, in FIG. 2, the first total voltage signal V_{TOTAL_AP} and the second total voltage signal V_{TOTAL_P} are expressed by the following equations.

V_{TOTAL_AP}=V_{REAL_AP}+V_{NOISE_AP}

V_{TOTAL_P}=V_{REAL_P}+V_{NOISE_P}

Also, the first noise signal V_{NOISE_AP} and the second noise signal V_{NOISE_P} are

V_{NOISE_AP}=V_{NOISE_P}

so that the output signal V_{OUT} is

V_{OUT} =V_{TOTAL_AP}−V_{TOTAL_P}=(V_{REAL_AP}+V_{NOISE_AP})−(V_{REAL_P}+V_{NOISE_P})=V_{REAL_AP}+V_{NOISE_AP}−V_{REAL_P}−V_{NOISE_P}=V_{REAL_AP}−V_{REAL_P}≈V_{REAL_AP}(∵V_{REAL_P}≈0).

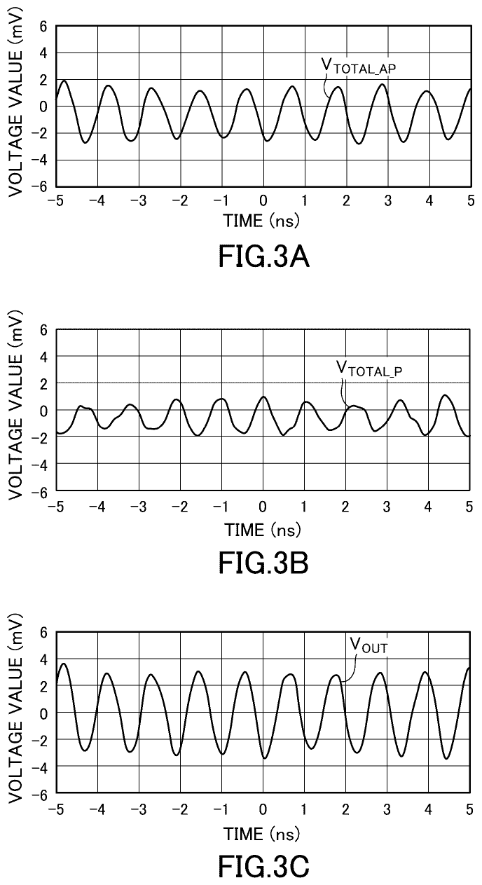

FIG. 3A shows the time waveform of the first total voltage signal V_{TOTAL_AP} output from the first magnetic element 10, FIG. 3B shows the time waveform of the second total voltage signal V_{TOTAL_P} output from the second magnetic element 20, and FIG. 3C shows the time waveform of the output signal V_{OUT} output from the differential synthesis circuit 30. As can be seen from FIGS. 3A, 3B, and 3C, the second total voltage signal V_{TOTAL_P} output from the second magnetic element 20 in the parallel magnetization state has a smaller amplitude than that of the first total voltage signal V_{TOTAL_AP} output from the first magnetic element 10 in the anti-parallel magnetization state, and the second total voltage signal V_{TOTAL_P} is in an opposite phase to the first total voltage signal V_{TOTAL_AP}. It can be seen that the output signal V_{OUT} output from the differential synthesis circuit 30 has a time waveform in which the first total voltage signal V_{TOTAL_AP}, which is mainly composed of the first real signal V_{REAL_AP}, or the first real signal V_{REAL_AP} has been amplified in amplitude.

As described above, the optical detection device 101 of the first embodiment can remove out-of-phase noise signals that are generated when light having an optical signal is irradiated onto a magnetic element, and can amplify a voltage signal corresponding to the optical signal.

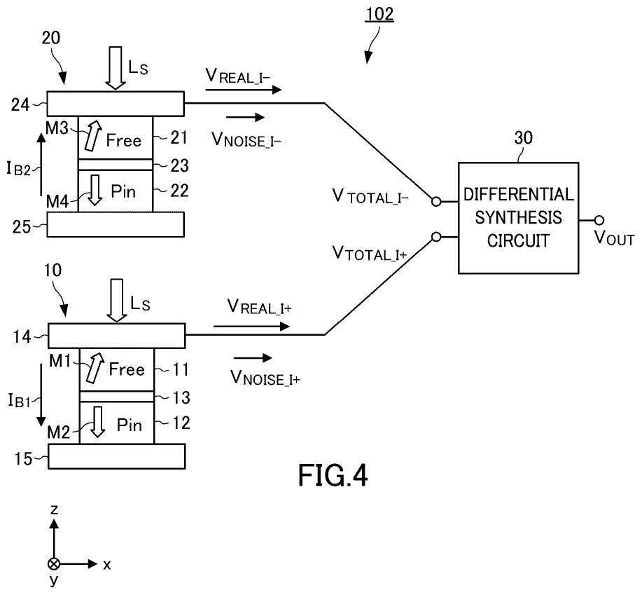

Next, a second embodiment of the present disclosure will be described. FIG. 4 is a diagram showing a schematic configuration of an optical detection device 102 according to a second embodiment of the present disclosure. The second embodiment differs from the above basic configuration in that the direction of the bias current flowing through the first magnetic element 10 and the second magnetic element 20 is specified. The other configuration is the same as the basic configuration described above, and the same components are given the same reference numerals, and the descriptions are omitted as appropriate.

As shown in FIG. 4, in the optical detection device 102, the magnetization directions of the first ferromagnetic layer 11 and the second ferromagnetic layer 12 of the first magnetic element 10 are antiparallel, and the magnetization directions of the third ferromagnetic layer 21 and the fourth ferromagnetic layer 22 of the second magnetic element 20 are antiparallel. In other words, both the first magnetic element 10 and the second magnetic element 20 are set to an antiparallel magnetization state.

As for the bias current, a first bias current IB1 is passed from the first ferromagnetic layer 11 of the free layer to the second ferromagnetic layer 12 of the pinned layer, and a second bias current IB2 is passed from the fourth ferromagnetic layer 22 of the pinned layer to the third ferromagnetic layer 21 of the free layer. Alternatively, a first bias current IB1 may be passed from the second ferromagnetic layer 12 of the pinned layer to the first ferromagnetic layer 11 of the free layer, and a second bias current IB2 may be passed from the third ferromagnetic layer 21 of the free layer to the fourth ferromagnetic layer 22 of the pinned layer.

With this configuration, the first real signal V_{REAL_I+} output from the first magnetic element 10 and the second real signal V_{REAL_I-} output from the second magnetic element 20 can be made to have opposite phases (phase difference of 180°).

In the differential synthesis circuit 30, the first noise signal V_{NOISE_I+} and the second noise signal V_{NOISE_I-}, which are in phase, cancel each other. The first real signal V_{REAL_I+} and the second real signal V_{REAL_I-}, which are in opposite phase, are substantially added together. As a result, the output signal V_{OUT} or its peak-to-peak value is amplified.

In more detail, in FIG. 4, the first total voltage signal V_{TOTAL_I+} and the second total voltage signal V_{TOTAL_I-} are expressed as follows:

V_{TOTAL_I+}=V_{REAL_I+}+V_{NOISE_I+}

V_{TOTAL_I-}=V_{REAL_I-}+V_{NOISE_I-}

Also, the first noise signal V_{NOISE_I+} and the second noise signal V_{NOISE_I-} are

V_{NOISE_I+}=V_{NOISE_I-},

so that the output signal V_{OUT} is

V_{OUT}=V_{TOTAL_I+}−V_{TOTAL_I-}=(V_{REAL_I+}+V_{NOISE_I+})−(V_{REAL_I-}+V_{NOISE_I-})=V_{REAL_I+}−V_{REAL_I-}.

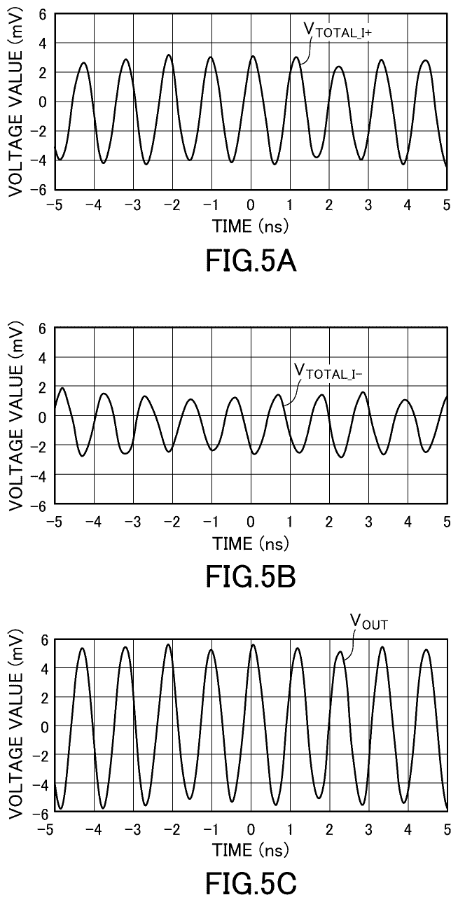

FIG. 5A shows the time waveform of the first total voltage signal V_{TOTAL_I+} output from the first magnetic element 10, FIG. 5B shows the time waveform of the second total voltage signal V_{TOTAL_I-} output from the second magnetic element 20, and FIG. 5C shows the time waveform of the output signal V_{OUT} output from the differential synthesis circuit 30. As can be seen from FIG. 5 A, 5B, and 5C, the second total voltage signal V_{TOTAL_I-} output from the second magnetic element 20 in the antiparallel magnetization state in which a bias current IB2 flows from the pinned layer to the free layer has a smaller amplitude than that of the first total voltage signal V_{TOTAL_I+} output from the first magnetic element 10 in the antiparallel magnetization state, and the second total voltage signal V_{TOTAL_I-} is in an opposite phase to the first total voltage signal V_{TOTAL_I+}. It can be seen that the output signal V_{OUT} output from the differential synthesis circuit 30 has a time waveform in which the first total voltage signal V_{TOTAL_I+} having the first real signal V_{REAL_I+} as a main component or the first real signal V_{REAL_I+} is amplified in amplitude.

As described above, the optical detection device 102 of the second embodiment in a similar manner to the first embodiment, can remove a phase-shifted noise signal that is generated when light having an optical signal is irradiated onto a magnetic element, and can amplify a voltage signal corresponding to the optical signal.

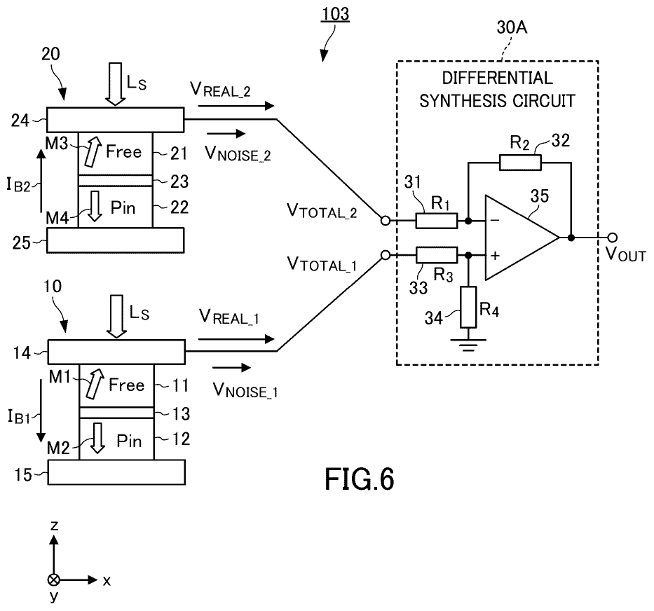

A third embodiment of the present disclosure will be described. FIG. 6 is a diagram showing a schematic configuration of an optical detection device 103 according to a third embodiment of the present disclosure. The third embodiment differs from the above basic configuration in that the configuration of the differential synthesis circuit 30A is specified. The other configurations are the same as the above basic configuration, and the same components are given the same reference numerals, and the descriptions are omitted as appropriate.

As shown in FIG. 6, in the optical detection device 103, the differential synthesis circuit 30A is configured using an operational amplifier 35. Specifically, the first electrode 14 of the first magnetic element 10 is connected to the non-inverting input terminal of the operational amplifier 35 via a resistor 33(R3). The third electrode 24 of the second magnetic element 20 is connected to the inverting input terminal of the operational amplifier 35 via a resistor 31(R1). The output terminal of the operational amplifier 35 is connected to the inverting input terminal via a resistor 32(R2). The non-inverting input terminal is grounded via a resistor 34(R4).

In the optical detection device 103, in the first magnetic element 10, the direction of magnetization M1 of the first ferromagnetic layer 11 and the direction of magnetization M2 of the second ferromagnetic layer 12 are antiparallel, and in the second magnetic element 20, the direction of magnetization M3 of the third ferromagnetic layer 21 and the direction of magnetization M4 of the fourth ferromagnetic layer 22 are antiparallel. In other words, both the first magnetic element 10 and the second magnetic element 20 are set to an antiparallel magnetization state.

As for the bias current, a first bias current IB1 is passed from the first ferromagnetic layer 11 of the free layer to the second ferromagnetic layer 12 of the pinned layer, and a second bias current IB2 is passed from the fourth ferromagnetic layer 22 of the pinned layer to the third ferromagnetic layer 21 of the free layer. Alternatively, the first bias current IB1 may be passed from the second ferromagnetic layer 12 of the pinned layer to the first ferromagnetic layer 11 of the free layer, and the second bias current IB2 may be passed from the third ferromagnetic layer 21 of the free layer to the fourth ferromagnetic layer 22 of the pinned layer.

Alternatively, the first magnetic element 10 may be set to an antiparallel magnetization state, and the second magnetic element 20 may be set to a parallel magnetization state. In this case, the first bias current IB1 is passed from the second ferromagnetic layer 12 of the pinned layer to the first ferromagnetic layer 11 of the free layer, and the second bias current IB2 is passed from the fourth ferromagnetic layer 22 of the pinned layer to the third ferromagnetic layer 21 of the free layer. Alternatively, the first bias current IB1 may be passed from the first ferromagnetic layer 11 of the free layer to the second ferromagnetic layer 12 of the pinned layer, and the second bias current IB2 is passed from the third ferromagnetic layer 21 of the free layer to the fourth ferromagnetic layer 22 of the pinned layer.

This configuration makes it possible to allow the first real signal V_{REAL_1} output from the first magnetic element 10 and the second real signal V_{REAL_2} output from the second magnetic element 20 to be in opposite phase (phase difference of 180°). On the other hand, the first noise signal V_{NOISE_1} and the second noise signal V_{NOISE_2} are in phase.

In the differential synthesis circuit 30A, the first noise signal V_{NOISE_1} and the second noise signal V_{NOISE_2}, which are in phase, cancel each other. The first real signal V_{REAL_1} and the second real signal V_{REAL_2}, which are in opposite phase, are substantially added together. As a result, the output signal V_{OUT} or its peak-to-peak value is amplified.

In more detail, in FIG. 6, the first total voltage signal V_{TOTAL_1} and the second total voltage signal V_{TOTAL_2} are expressed as follows:

If R₁=R₂=R₃=R₄,

V_{TOTAL_1}=V_{REAL_1}+V_{NOISE_1}

V_{TOTAL_2}=V_{REAL_2}+V_{NOISE_2}

Also, the first noise signal V_{NOISE_1} and the second noise signal V_{NOISE_2} are

V_{NOISE_1}=V_{NOISE_2},

so that the output signal V_{OUT} is

V_{OUT}={(R₁+R₂)/R₁}·{R₁/(R₃+R₄)}V_{TOTAL_1}−(R₂/R₁)V_{TOTAL_2}=V_{TOTAL_1}−V_{TOTAL_2}=(V_{REAL_1}+V_{NOISE_1})−(V_{REAL_2}+V_{NOISE_2})=V_{REAL_1}−V_{REAL_2}

As described above, the optical detection device 103 of the third embodiment can easily realize a highly accurate differential synthesis circuit 30A in addition to the effects obtained from the basic configuration described above.

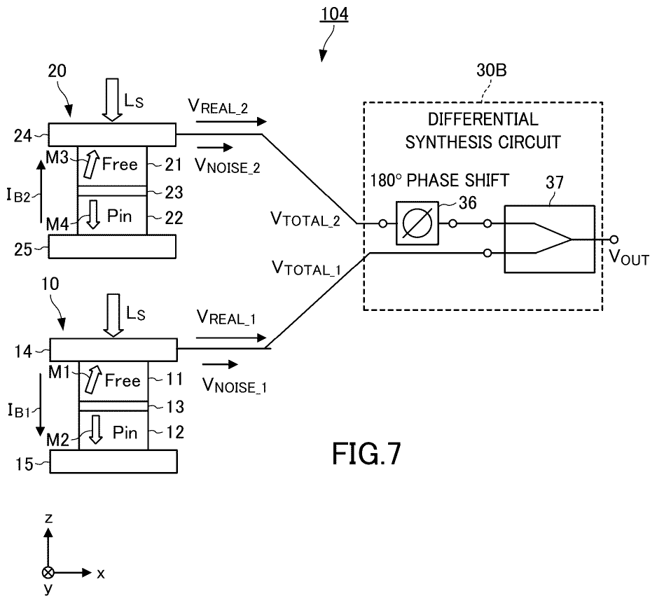

Next, a fourth embodiment of the present disclosure will be described. FIG. 7 is a diagram showing the schematic configuration of an optical detection device 104 according to a fourth embodiment of the present disclosure. The fourth embodiment differs from the basic configuration described above in that the configuration of the differential synthesis circuit 30B is specified. The other configurations are the same as the basic configuration described above, and the same components are given the same reference numerals and descriptions are omitted as appropriate.

As shown in FIG. 7, in the optical detection device 104, the differential synthesis circuit 30B includes a 180° phase shift circuit 36 that inputs the second total voltage signal V_{TOTAL_2} output from the second magnetic element 20 and phase-shifts the second total voltage signal V_{TOTAL_2} by 180°, and a power combiner 37 that synthesizes the 180° phase-shifted second total voltage signal V_{TOTAL_2} and the first total voltage signal V_{TOTAL_1} output from the first magnetic element 10.

In the optical detection device 104, the magnetization directions of the first ferromagnetic layer 11 and the second ferromagnetic layer 12 in the first magnetic element 10 are antiparallel, and the magnetization directions of the third ferromagnetic layer 21 and the fourth ferromagnetic layer 22 in the second magnetic element 20 are antiparallel. That is, both the first magnetic element 10 and the second magnetic element 20 are set to an antiparallel magnetization state.

As for the bias current, a first bias current IB1 is passed from the first ferromagnetic layer 11 of the free layer to the second ferromagnetic layer 12 of the pinned layer, and a second bias current IB2 is passed from the fourth ferromagnetic layer 22 of the pinned layer to the third ferromagnetic layer 21 of the free layer. Alternatively, the first bias current IB1 may be passed from the second ferromagnetic layer 12 of the pinned layer to the first ferromagnetic layer 11 of the free layer, and the second bias current IB2 may be passed from the third ferromagnetic layer 21 of the free layer to the fourth ferromagnetic layer 22 of the pinned layer.

Alternatively, the first magnetic element 10 may be set to an antiparallel magnetization state, and the second magnetic element 20 may be set to a parallel magnetization state. In this case, the first bias current IB1 is passed from the second ferromagnetic layer 12 of the pinned layer to the first ferromagnetic layer 11 of the free layer, and the second bias current IB2 is passed from the fourth ferromagnetic layer 22 of the pinned layer to the third ferromagnetic layer 21 of the free layer. Alternatively, the first bias current IB1 may be passed from the first ferromagnetic layer 11 of the free layer to the second ferromagnetic layer 12 of the pinned layer, and the second bias current IB2 may be passed from the third ferromagnetic layer 21 of the free layer to the fourth ferromagnetic layer 22 of the pinned layer.

With this configuration, the first real signal V_{REAL_1} output from the first magnetic element 10 and the second real signal V_{REAL_2} output from the second magnetic element 20 can be made to have opposite phases (phase difference of 180°). On the other hand, the first noise signal V_{NOISE_1} and the second noise signal V_{NOISE_2} are in phase.

The second noise signal V_{NOISE_2} is phase shifted by 180° by the 180° phase shift circuit 36 and input to the power combiner 37, and the first noise signal V_{NOISE_1} is input to the power combiner 37 as is. In other words, the first noise signal V_{NOISE_1} and the second noise signal V_{NOISE_2} are in opposite phase and are input to the power combiner 37 and cancel each other.

The second real signal V_{REAL_2} is phase shifted by 180° by the 180° phase shift circuit 36 and input to the power combiner 37, and the first real signal V_{REAL_1} is input to the power combiner 37 as is. That is, the first real signal V_{REAL_1} and the second real signal V_{REAL_2} have the same phase and are input to the power combiner 37, where the first real signal V_{REAL_1} and the second real signal V_{REAL_2} are synthesized, and the output signal VOUT or its peak-to-peak value is amplified.

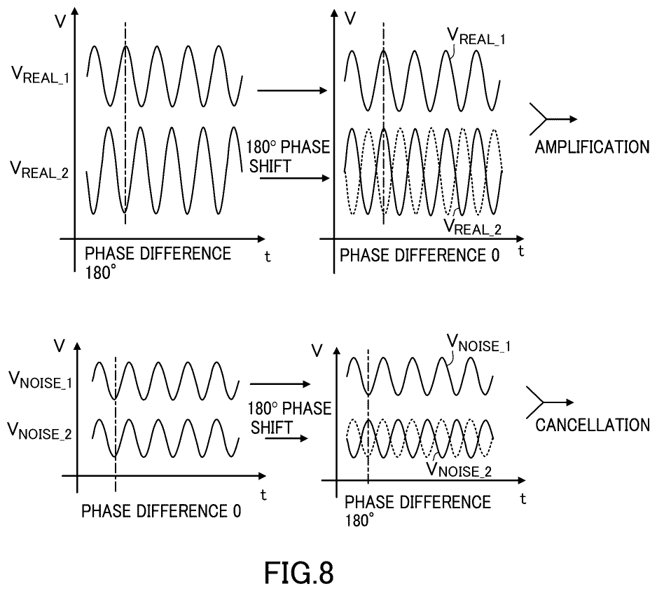

The diagram on the upper left of FIG. 8 shows the time waveforms of the first real signal V_{REAL_1} and the second real signal V_{REAL_2} before being input to the differential synthesis circuit 30B. The diagram on the upper right of FIG. 8 shows the time waveforms of the first real signal V_{REAL_1} and the second real signal V_{REAL_2} before being input to the power combiner 37 of the differential synthesis circuit 30B. The first real signal V_{REAL_1} and the second real signal V_{REAL_2} before being input to the differential synthesis circuit 30B have a phase difference of 180°. The second real signal V_{REAL_2} is phase-shifted by 180° by the 180° phase shift circuit 36. Therefore, the first real signal V_{REAL_1} and the second real signal V_{REAL_2} have a phase difference of 0° (i.e., the same phase) before being input to the power combiner 37. As a result, the first real signal V_{REAL_1} and the second real signal V_{REAL_2} are synthesized by the power combiner 37.

On the other hand, the diagram on the left at the bottom of FIG. 8 is a diagram showing the time waveforms of the first noise signal V_{NOISE_1} and the second noise signal V_{NOISE_2} before being input to the differential synthesis circuit 30B. The diagram on the right at the bottom of FIG. 8 is a diagram showing the time waveforms of the first noise signal V_{NOISE_1} and the second noise signal V_{NOISE_2} before being input to the power combiner 37 of the differential synthesis circuit 30B. The first noise signal V_{NOISE_1} and the second noise signal V_{NOISE_2} have a phase difference of 0° (i.e., the same phase) before being input to the differential synthesis circuit 30B. The second noise signal V_{NOISE_2} is phase-shifted by 180° by the 180° phase shift circuit 36. Therefore, the first noise signal V_{NOISE_1} and the second noise signal V_{NOISE_2} have a phase difference of 180° (i.e., opposite phase) before being input to the power combiner 37. As a result, the first noise signal V_{NOISE_1} and the second noise signal V_{NOISE_2} are canceled by the power combiner 37.

As described above, the optical detection device 104 of the fourth embodiment can easily realize a highly accurate differential synthesis circuit 30B in addition to the effects obtained from the basic configuration described above.

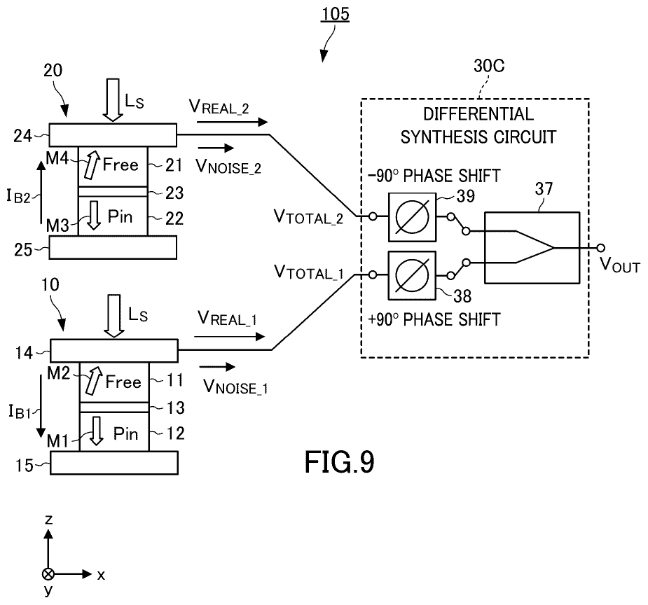

Next, a fifth embodiment of the present disclosure will be described. FIG. 9 is a diagram showing the schematic configuration of an optical detection device 105 according to a fifth embodiment of the present disclosure. The fifth embodiment differs from the basic configuration described above in that the configuration of the differential synthesis circuit 30C is specified. The other configurations are the same as the basic configuration described above, and the same components are given the same reference numerals and descriptions are omitted as appropriate.

As shown in FIG. 9, in the optical detection device 105, the differential synthesis circuit 30C includes a +90° phase shift circuit 38 that inputs the first total voltage signal V_{TOTAL_1} output from the first magnetic element 10 and phase-shifts the first total voltage signal V_{TOTAL_1} by +90°, a −90° phase shift circuit 39 that inputs the second total voltage signal V_{TOTAL_2} output from the second magnetic element 20 and phase-shifts the second total voltage signal V_{TOTAL_2} by −90°, and a power combiner 37 that synthesizes the +90°phase-shifted first total voltage signal V_{TOTAL_1} and the −90° phase-shifted second total voltage signal V_{TOTAL_2}.

In the optical detection device 105, the magnetization directions of the first ferromagnetic layer 11 and the second ferromagnetic layer 12 in the first magnetic element 10 are antiparallel, and the magnetization directions of the third ferromagnetic layer 21 and the fourth ferromagnetic layer 22 in the second magnetic element 20 are antiparallel. In other words, both the first magnetic element 10 and the second magnetic element 20 are set to an antiparallel magnetization state.

As for the bias current, a first bias current IB1 is passed from the first ferromagnetic layer 11 of the free layer to the second ferromagnetic layer 12 of the pinned layer, and a second bias current IB2 is passed from the fourth ferromagnetic layer 22 of the pinned layer to the third ferromagnetic layer 21 of the free layer. Alternatively, the first bias current IB1 may be passed from the second ferromagnetic layer 12 of the pinned layer to the first ferromagnetic layer 11 of the free layer, and the second bias current IB2 may be passed from the third ferromagnetic layer 21 of the free layer to the fourth ferromagnetic layer 22 of the pinned layer.

Alternatively, the first magnetic element 10 may be set to an antiparallel magnetization state, and the second magnetic element 20 may be set to a parallel magnetization state. In this case, the first bias current IB1 is passed from the second ferromagnetic layer 12 of the pinned layer to the first ferromagnetic layer 11 of the free layer, and the second bias current IB2 is passed from the fourth ferromagnetic layer 22 of the pinned layer to the third ferromagnetic layer 21 of the free layer. Alternatively, the first bias current IB1 may be passed from the first ferromagnetic layer 11 of the free layer to the second ferromagnetic layer 12 of the pinned layer, and the second bias current IB2 may be passed from the third ferromagnetic layer 21 of the free layer to the fourth ferromagnetic layer 22 of the pinned layer.

This configuration makes it possible to allow the first real signal V_{REAL_1} output from the first magnetic element 10 and the second real signal V_{REAL_2} output from the second magnetic element 20 to be in opposite phase (phase difference of 180°). On the other hand, the first noise signal V_{NOISE_1} and the second noise signal V_{NOISE_2} are in phase.

The first noise signal V_{NOISE_1} is phase shifted by +90° by the +90° phase shift circuit 38 and input to the power combiner 37, and the second noise signal V_{NOISE_2} is phase shifted by −90° by the −90° phase shift circuit 39 and input to the power combiner 37. In other words, the first noise signal V_{NOISE_1} and the second noise signal V_{NOISE_2} are in opposite phase and are input to the power combiner 37 to cancel each other.

The first real signal V_{REAL_1} is phase-shifted by +90° by the +90° phase shift circuit 38 and input to the power combiner 37, and the second real signal V_{REAL_2} is phase-shifted by −90° by the −90° phase shift circuit 39 and input to the power combiner 37. In other words, the first real signal V_{REAL_1} and the second real signal V_{REAL_2} are in phase and input to the power combiner 37, where the first real signal V_{REAL_1} and the second real signal V_{REAL_2} are synthesized, and the output signal VOUT or its peak-to-peak value is amplified.

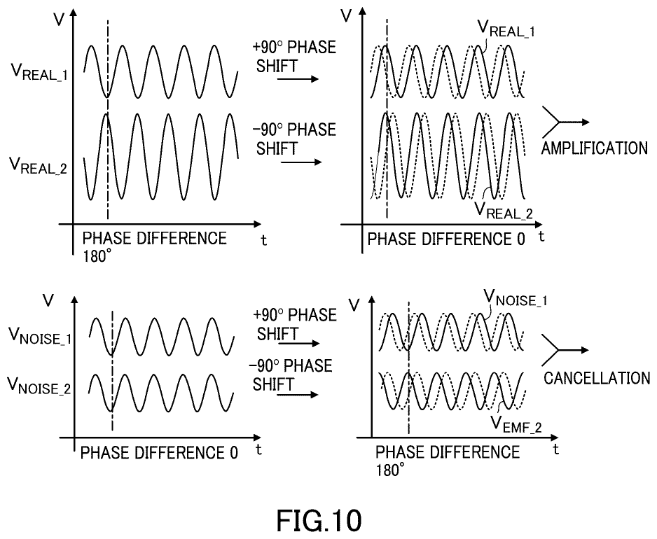

The diagram on the upper left of FIG. 10 shows the time waveforms of the first real signal V_{REAL_1} and the second real signal V_{REAL_2} before being input to the differential synthesis circuit 30C. The diagram on the upper right of FIG. 10 is a diagram showing the time waveforms of the first real signal V_{REAL_1} and the second real signal V_{REAL_2} before being input to the power combiner 37 of the differential synthesis circuit 30C. The first real signal V_{REAL_1} and the second real signal V_{REAL_2} before being input to the differential synthesis circuit 30C have a phase difference of 180°. The first real signal V_{REAL_1} is phase-shifted by +90° by the +90° phase shift circuit 38, and the second real signal V_{REAL_2} is phase-shifted by −90° by the −90° phase shift circuit 39. Therefore, the first real signal V_{REAL_1} and the second real signal V_{REAL_2} before being input to the power combiner 37 have a phase difference of 0° (i.e., the same phase). As a result, the first real signal V_{REAL_1} and the second real signal V_{REAL_2} are synthesized by the power combiner 37.

On the other hand, the diagram on the bottom left of FIG. 10 is a diagram showing the time waveforms of the first noise signal V_{NOISE_1} and the second noise signal V_{NOISE_2} before they are input to the differential synthesis circuit 30C. The diagram on the bottom right of FIG. 10 is a diagram showing the time waveforms of the first noise signal V_{NOISE_1} and the second noise signal V_{NOISE_2} before they are input to the power combiner 37 of the differential synthesis circuit 30C. The first noise signal V_{NOISE_1} and the second noise signal V_{NOISE_2} before they are input to the differential synthesis circuit 30C have a phase difference of 0°(i.e., they are in phase). The first noise signal V_{NOISE_1} is phase-shifted by +90° by the +90° phase shift circuit 38, and the second noise signal V_{NOISE_2} is phase-shifted by −90° by the −90° phase shift circuit 39. Therefore, the first noise signal V_{NOISE_1} and the second noise signal V_{NOISE_2} have a phase difference of 180° (i.e., opposite phase) before being input to the power combiner 37. As a result, the first noise signal V_{NOISE_1} and the second noise signal V_{NOISE_2} are cancelled out by the power combiner 37.

As described above, the optical detection device 105 of the fifth embodiment can easily realize a highly accurate differential synthesis circuit 30C in addition to the effects obtained by the basic configuration.

The optical detection devices 100 to 105 according to the above embodiments can be applied to, for example, a transceiver device 400 in a communication system.

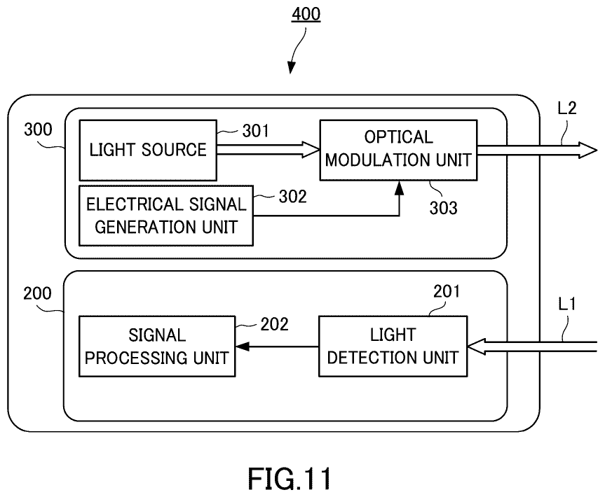

FIG. 11 is a diagram showing the configuration of a transceiver device 400 as an application example. As shown in FIG. 11, the transceiver device 400 includes a reception device 200 and a transmission device 300. The reception device 200 receives an optical signal L1, and the transmission device 300 transmits an optical signal L2.

The reception device 200 includes, for example, a light detection unit 201 and a signal processing unit 202. The light detection unit 201 is any one of the optical detection devices 100 to 105 according to the above-described embodiments. In the following, a case where the optical detection device 100 is used as the light detection unit 201 will be described. The light detection unit 201 converts the optical signal L1 into an electrical signal. The light detection unit 201 is irradiated with light including the optical signal L1 whose light intensity changes. Specifically, the first ferromagnetic layer 11 of the first magnetic element 10 and the third ferromagnetic layer 21 of the second magnetic element 20 are simultaneously irradiated with the same light including the optical signal L1. The light including the optical signal L1 may be, for example, light having a wavelength of 400 nm or more and 1500 nm or less.

Lens may be disposed on the first electrode 14 side and the third electrode 24 side in the stacking direction of the light detection unit 201, respectively, so that the light that passes through the lens and collected is irradiated simultaneously to the first ferromagnetic layer 11 and the third ferromagnetic layer 21. The lens may be formed during the wafer process in which the light detection unit 201 is formed.

In addition, the light that passes through the waveguide may be irradiated simultaneously to the first ferromagnetic layer 11 of the first magnetic element 10 and the third ferromagnetic layer 21 of the second magnetic element 20 in the light detection unit 201. The light irradiated to the first ferromagnetic layer 11 of the first magnetic element 10 and the third ferromagnetic layer 21 of the second magnetic element 20 in the light detection unit 201 is, for example, laser light. The signal processing unit 202 processes the electrical signal converted by the light detection unit 201. The signal processing unit 202 demodulates the modulated signal included in the light signal L1 by processing the electrical signal generated by the light detection unit 201.

The transmission device 300 includes, for example, a light source 301, an electrical signal generation unit 302, and an optical modulation unit 303. The light source 301 is, for example, a laser element. The light source 301 may be outside the transmission device 300. The electrical signal generation unit 302 generates an electrical signal based on the transmission information. The electrical signal generation unit 302 may be integrated with the signal conversion element of the signal processing unit 202. The optical modulation unit 303 modulates the light output from the light source 301 based on the electrical signal generated by the electrical signal generation unit 302, and outputs an optical signal L2. The light output from the light source 301 may be light with a wavelength of, for example, 400 nm or more and 1500 nm or less.

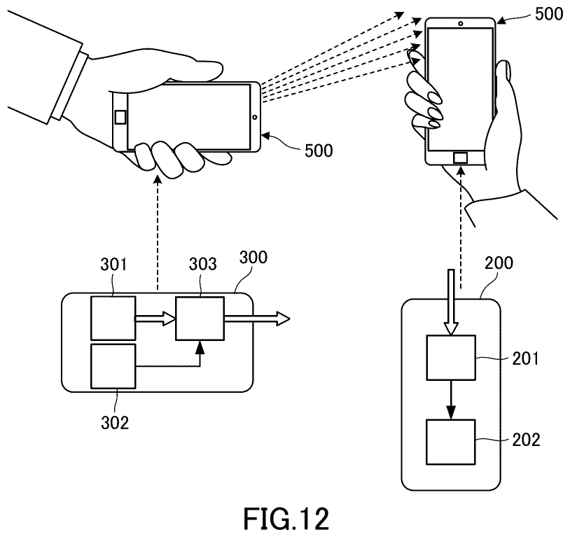

FIG. 12 is a conceptual diagram of an example of a communication system. The communication system shown in FIG. 12 has two terminal devices 500. The terminal devices 500 are, for example, a smartphone, a tablet, a personal computer, etc.

Each of the terminal devices 500 includes a transceiver device 400 having a reception device 200 and a transmission device 300. An optical signal transmitted from the transmission device 300 of one of the terminal devices 500 is received by the reception device 200 of the other terminal device 500. The light used for transmission and reception between the terminal devices 500 may be, for example, visible light, or light with a wavelength of 400 nm or more and 1500 nm or less. The reception device 200 has any of the above-mentioned optical detection devices 100 to 105 as the light detection unit 201.

The above communication system may also be, for example, a communication system that wirelessly transmits and receives optical signals such as near-infrared light between mobile terminals such as smartphones and tablets. The above communication system may also be, for example, a communication system that wirelessly transmits and receives optical signals such as near-infrared light between a mobile terminal and an information processing device such as a personal computer.

The above communication system may be a communication system for short-or medium-distance communication such as within a data center or between data centers, or for long-distance communication such as between cities. The transceiver device 400 is installed, for example, in a data center.

The optical detection devices 100 to 105 of the above embodiment may be applied to the light detection unit 201 of the reception device 200 provided in the transceiver device 400 that transmits and receives optical signals such as laser light, for example, in a communication system in which a plurality of transceiver devices are connected by optical fibers.

The optical detection devices 100 to 105 of the above embodiment may be applied to an optical sensor device 700 such as an image sensor in which a plurality of optical detection devices 100 are arranged one-dimensionally or two-dimensionally. Such an optical sensor device 700 may be used in a terminal device such as a smartphone, a tablet, a personal computer, or a digital camera.

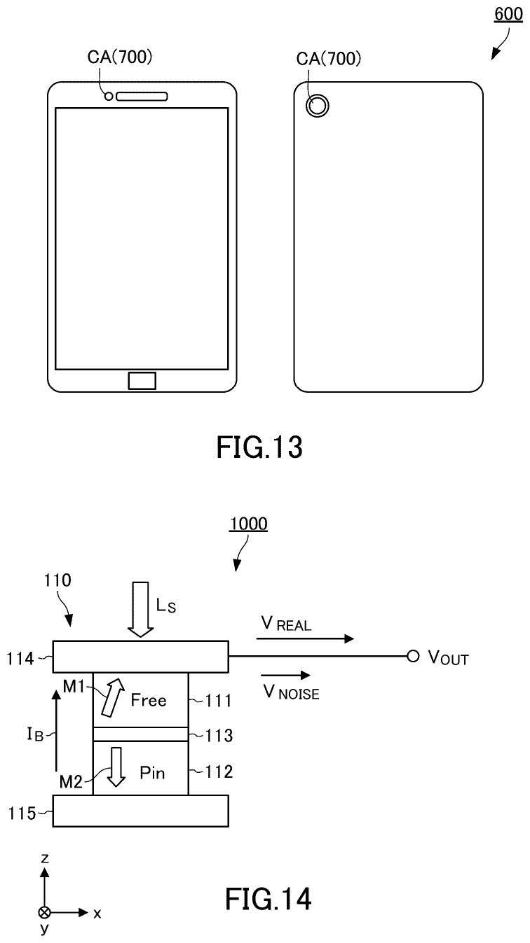

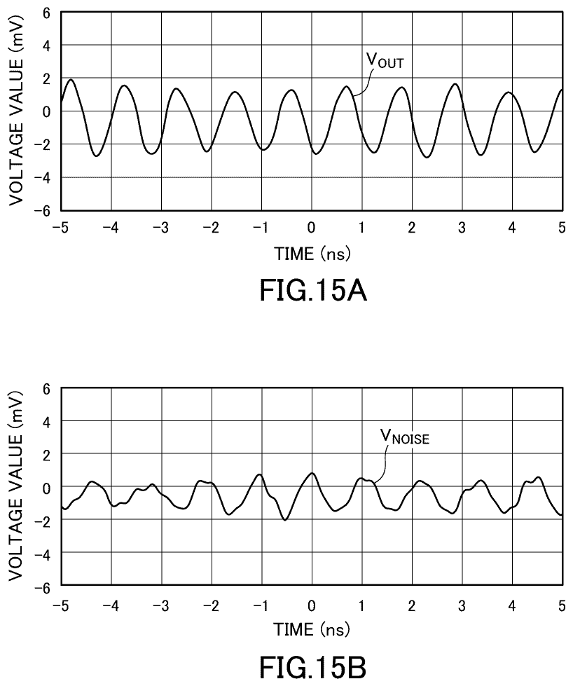

FIG. 13 is a schematic diagram of an example of a terminal device 600. The left side of FIG. 13 is the front side of the terminal device 600, and the right side of FIG. 13 is the back side of the terminal device 600. The terminal device 600 has a camera CA. The optical sensor device 700 described above can be used as an imaging element of this camera CA. In FIG. 13, a smartphone is illustrated as an example of the terminal device 600, but this is not limited to this case. The terminal device 600 can be, for example, a tablet, a personal computer, a digital camera, etc., in addition to a smartphone.

The present disclosure is not limited to the above embodiments, and various modifications and changes are possible within the scope of the gist of the present disclosure described in the claims.

As described above, the present disclosure has the effect of being able to remove out-of-phase noise signals that are generated when light having an optical signal is irradiated onto a magnetic element, and is useful in the optical detection devices and the transceiver devices in general.

### APPENDIX

The optical detection device according to the present disclosure comprises a first magnetic element including a first ferromagnetic layer, a second ferromagnetic layer, and a first spacer layer sandwiched between the first ferromagnetic layer and the second ferromagnetic layer, wherein when the first ferromagnetic layer is irradiated with light including an optical signal, the first magnetic element generates a first voltage signal in response to the optical signal, a second magnetic element including a third ferromagnetic layer, a fourth ferromagnetic layer, and a second spacer layer sandwiched between the third ferromagnetic layer and the fourth ferromagnetic layer, wherein when the third ferromagnetic layer is simultaneously irradiated with the light, the second magnetic element generates a second voltage signal in opposite phase to the first voltage signal corresponding to the optical signal, and a differential synthesis circuit that differentially synthesizes a first total voltage signal including the first voltage signal output from the first magnetic element and a second total voltage signal including the second voltage signal output from the second magnetic element including the second voltage signal.

As described above, when light having the same optical signal is irradiated simultaneously to the first magnetic element and the second magnetic element, a first voltage signal corresponding to the optical signal is generated from the first magnetic element, and a second voltage signal corresponding to the optical signal and having an opposite phase to the first voltage signal is generated from the second magnetic element. At the same time, a first noise signal out of phase with respect to the first voltage signal is generated from the first magnetic element, and a second noise signal out of phase with respect to the second voltage signal is generated from the second magnetic element. That is, the first voltage signal plus the first noise signal is the first total voltage signal, and the first total voltage signal is input to the differential synthesis circuit. Similarly, the second voltage signal plus the second noise signal is the second total voltage signal, and the second total voltage signal is input to the differential synthesis circuit. Here, the first voltage signal and the second voltage signal are in opposite phase, and the first noise signal and the second noise signal are in phase. Therefore, the differential synthesis circuit cancels the first and second noise signals of the same phase, and substantially adds up the first and second voltage signals of opposite phases. As a result, the above configuration can remove out-of-phase noise signals that are generated when light having an optical signal is irradiated onto a magnetic element, and can amplify a voltage signal corresponding to the optical signal.

The optical detection device according to the present disclosure may have magnetization directions of the first ferromagnetic layer and the second ferromagnetic layer of the first magnetic element that are antiparallel, and magnetization directions of the third ferromagnetic layer and the fourth ferromagnetic layer of the second magnetic element that are parallel.

This configuration can make the first voltage signal output from the first magnetic element and the second voltage signal output from the second magnetic element have opposite phases. As a result, in the differential synthesis circuit, the first noise signal and the second noise signal of the same phase cancel out each other, and substantially adds up the first and second voltage signals of opposite phases. As a result, the above configuration can eliminate out-of-phase noise signals that are generated when light having an optical signal is irradiated onto a magnetic element, and can amplify a voltage signal corresponding to the optical signal.

The optical detection device according to the present disclosure may be configured such that a first bias current flows from the first ferromagnetic layer toward the second ferromagnetic layer or in the opposite direction, and a second bias current flows from the fourth ferromagnetic layer toward the third ferromagnetic layer or in the opposite direction.

With this configuration, the optical detection device of the present disclosure can make the first voltage signal output from the first magnetic element and the second voltage signal output from the second magnetic element out of phase. Therefore, in the differential synthesis circuit, the first noise signal and the second noise signal, which are in phase, cancel each other, and the first voltage signal and the second voltage signal, which are in opposite phase, are substantially added together. As a result, the above configuration can eliminate out-of-phase noise signals that are generated when light having an optical signal is irradiated onto a magnetic element, and can amplify a voltage signal corresponding to the optical signal.

In the optical detection device according to the present disclosure, the differential synthesis circuit may be configured using an operational amplifier.

This configuration makes it easy to realize a highly accurate differential synthesis circuit.

In the optical detection device according to the present disclosure, the differential synthesis circuit may include a 180° phase shift circuit that inputs the second total voltage signal output from the second magnetic element and phase-shifts the second total voltage signal by 180°, and a power combiner that combines the 180° phase-shifted second total voltage signal and the first total voltage signal output from the first magnetic element.

With this configuration, the second noise signal is phase-shifted by 180° by the 180° phase shift circuit and input to the power combiner, and the first noise signal is input to the power combiner as is. That is, the first noise signal and the second noise signal are in opposite phase and are input to the power combiner to cancel each other. The second voltage signal is phase-shifted by 180° by the 180° phase shift circuit and input to the power combiner, and the first voltage signal is input to the power combiner as is. That is, the first voltage signal and the second voltage signal are in phase and are input to a power combiner, where the first voltage signal and the second voltage signal are synthesized. Therefore, with the above configuration, it is possible to remove a noise signal with a phase shift that is generated when light having an optical signal is irradiated onto a magnetic element, and to amplify a voltage signal corresponding to the optical signal.

In the optical detection device according to the present disclosure, the differential synthesis circuit may be configured to include a +90° phase shift circuit that inputs the first total voltage signal output from the first magnetic element and shifts the phase of the first total voltage signal by +90°, a −90° phase shift circuit that inputs the second total voltage signal output from the second magnetic element and shifts the phase of the second total voltage signal by −90°, and a power combiner that combines the +90° phase-shifted first total voltage signal and the −90° phase-shifted second total voltage signal.

With this configuration, the first noise signal is phase-shifted by +90° by the +90° phase shift circuit and input to the power combiner, and the second noise signal is phase-shifted by −90° by the −90° phase shift circuit and input to the power combiner. That is, the first noise signal and the second noise signal are in opposite phase and are input to the power combiner to cancel each other. The first voltage signal is phase-shifted by +90° by the +90° phase shift circuit and input to the power combiner, and the second voltage signal is phase-shifted by −90° by the −90° phase shift circuit and input to the power combiner. That is, the first voltage signal and the second voltage signal are in phase and are input to the power combiner to synthesize the first voltage signal and the second voltage signal. As a result, with the above configuration, it is possible to remove out-of-phase noise signals that are generated when light having an optical signal is irradiated to a magnetic element, and to amplify a voltage signal corresponding to the optical signal.

In the optical detection device according to the present disclosure, the first magnetic element further comprises a first electrode provided on the first ferromagnetic layer opposite to the first spacer layer and a second electrode provided on the second ferromagnetic layer opposite to the first spacer layer, and the second magnetic element further comprises a third electrode provided on the third ferromagnetic layer opposite to the second spacer layer and a fourth electrode provided on the fourth ferromagnetic layer opposite to the second spacer layer, and the first electrode and the third electrode may be transparent electrodes.

With this configuration, the light incident on the first magnetic element and the second magnetic element can be irradiated to the first ferromagnetic layer and the third ferromagnetic layer with almost no attenuation.

In order to achieve the above object, the transceiver device according to the present disclosure comprises a transmission device having a light source that emits light with a wavelength of 400 nm or more and 1500 nm or less, modulating and outputting the emitted light, and a reception device having any of the above-mentioned optical detection devices that detect light with a wavelength of 400 nm or more and 1500 nm or less, demodulating the detected light.

With this configuration, the optical detection device of the reception device can perform photoelectric conversion with high accuracy by receiving light in the above wavelength range. Also, since the light source of the transmission device emits light in the same wavelength range, a communication system with excellent reception performance can be efficiently constructed by each communication device which is equipped with this transceiver device.

According to the present disclosure, it is possible to provide the optical detection device and the transceiver device that can remove out-of-phase noise signals that are generated when light having an optical signal is irradiated onto the magnetic element.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

10 First magnetic element
11, 111 First ferromagnetic layer
12, 112 Second ferromagnetic layer
13 First spacer layer
14, 114 First electrode
15, 115 Second electrode
20 Second magnetic element
21 Third ferromagnetic layer
22 Fourth ferromagnetic layer
23 Second spacer layer
24 Third electrode
25 Fourth electrode
30, 30A, 30B, 30C Differential synthesis circuit
31, 32, 33, 34 Resistor
35 Operational amplifier
36 180° phase shift circuit
37 Power combiner
38 +90° phase shift circuit
39 −90° phase shift circuit
100, 101, 102, 103, 104, 105 Optical detection device
110 Magnetic element
113 Spacer layer
200 Reception device
201 Light detection unit
202 Signal processing unit
300 Transmission device
301 Light source
302 Electrical signal generation unit
303 Optical modulation unit
400 Transceiver device
500, 600 Terminal device
700 Optical sensor device
1000 Conventional optical detection device
M1, M2, M3, M4 Magnetization

What is claimed is:

1. An optical detection device comprising:
a first magnetic element including a first ferromagnetic layer, a second ferromagnetic layer, and a first spacer layer sandwiched between the first ferromagnetic layer and the second ferromagnetic layer, wherein when the first ferromagnetic layer is irradiated with light including an optical signal, the first magnetic element generates a first voltage signal in response to the optical signal;
a second magnetic element including a third ferromagnetic layer, a fourth ferromagnetic layer, and a second spacer layer sandwiched between the third ferromagnetic layer and the fourth ferromagnetic layer, wherein when the third ferromagnetic layer is simultaneously irradiated with the light, the second magnetic element generates a second voltage signal in opposite phase to the first voltage signal corresponding to the optical signal; and
a differential synthesis circuit that differentially synthesizes a first total voltage signal including the first voltage signal output from the first magnetic element and a second total voltage signal including the second voltage signal output from the second magnetic element including the second voltage signal.

2. The optical detection device as described in claim 1, where the differential synthesis circuit outputs the difference between the first total voltage signal and the second total voltage signal.

3. The optical detection device as described in claim 2, where the first total voltage signal is the sum of the first voltage signal and a first noise signal out of phase with respect to the first voltage signal,
the second total voltage signal is the sum of the second voltage signal and second noise signal out of phase with respect to the second voltage signal, and
the first noise signal and the second noise signal are in phase.

4. The optical detection device as described in claim 1, where the magnetization directions of the first ferromagnetic layer and the second ferromagnetic layer of the first magnetic element are antiparallel, and the magnetization directions of the third ferromagnetic layer and the fourth ferromagnetic layer of the second magnetic element are parallel.

5. The optical detection device as described in claim 1, where the magnetization directions of the first ferromagnetic layer and the second ferromagnetic layer of the first magnetic element are antiparallel, and the magnetization directions of the third ferromagnetic layer and the fourth ferromagnetic layer of the second magnetic element are antiparallel.

6. The optical detection device as described in claim 4, where a first bias current is passed from the second ferromagnetic layer to the first ferromagnetic layer or in the opposite direction, and a second bias current is passed from the fourth ferromagnetic layer to the third ferromagnetic layer or in the opposite direction.

7. The optical detection device as described in claim 5, where a first bias current is passed from the first ferromagnetic layer to the second ferromagnetic layer or in the opposite direction, and a second bias current is passed from the fourth ferromagnetic layer to the third ferromagnetic layer or in the opposite direction.

8. The optical detection device as described in claim 1, where the differential synthesis circuit is configured using an operational amplifier.

9. The optical detection device as described in claim 1, where the differential synthesis circuit comprises:
a 180° phase shift circuit that receives the second total voltage signal output from the second magnetic element and phase-shifts the second total voltage signal by 180°; and
a power combiner that combines the 180° phase-shifted second total voltage signal and the first total voltage signal output from the first magnetic element.

10. The optical detection device as described in claim 9, where the first total voltage signal is the sum of the first voltage signal and a first noise signal out of phase with respect to the first voltage signal,
the second total voltage signal is the sum of the second voltage signal and second noise signal out of phase with respect to the second voltage signal, and
the first noise signal and the second noise signal are in phase.

11. The optical detection device as described in claim 1, where the differential synthesis circuit comprises:
a +90° phase shift circuit that receives the first total voltage signal output from the first magnetic element and phase-shifts the first total voltage signal by +90°;
a −90° phase shift circuit that receives the second total voltage signal output from the second magnetic element and phase-shifts the second total voltage signal by −90°; and
a power combiner that combines the +90° phase-shifted first total voltage signal and the −90° phase-shifted second total voltage signal.

12. The optical detection device as described in claim 11, where the first total voltage signal is the sum of the first voltage signal and a first noise signal out of phase with respect to the first voltage signal,
the second total voltage signal is the sum of the second voltage signal and second noise signal out of phase with respect to the second voltage signal, and
the first noise signal and the second noise signal are in phase.

13. The optical detection device as described in claim 1, where
the first magnetic element further comprises a first electrode provided on the first ferromagnetic layer opposite to the first spacer layer, and a second electrode provided on the second ferromagnetic layer opposite to the first spacer layer, and
the second magnetic element further comprises a third electrode provided on the third ferromagnetic layer opposite to the second spacer layer, and a fourth electrode provided on the fourth ferromagnetic layer opposite to the second spacer layer,
the first electrode and the third electrode being transparent electrodes.

14. The optical detection device as described in claim 13, where the differential synthesis circuit is configured using an operational amplifier,
the operational amplifier comprises:
an inverting input terminal connected to the third electrode of the second magnetic element via a first resistor;
an output terminal connected to the inverting input terminal via a second resistor; and
a non-inverting input terminal connected to the first electrode of the first magnetic element via a third resistor,
wherein the non-inverting input terminal is grounded via a fourth resistor.

15. The optical detection device as described in claim 14, where the resistance values of the first resistor, the second resistor, the third resistor, and the fourth resistor are all equal.

16. The optical detection device as described in claim 1, where the first ferromagnetic layer and the second ferromagnetic layer are each composed of CoFeB, Co, Fe, or Ni.

17. The optical detection device as described in claim 13, where the first electrode and the third electrode are each composed of ITO, IZO, ZnO, or IGZO.

18. The optical detection device as described in claim 13, where the second electrode and the fourth electrode are each composed of Cu, Al, or Au.

19. The optical detection device as described in claim 1, where the first spacer layer and the second spacer layer each include aluminum oxide, magnesium oxide, titanium oxide, or silicon oxide.

20. A transceiver device comprising:
a transmission device that includes a light source that emits light having a wavelength of 400 nm or more and 1500 nm or less, and that modulates and outputs the emitted light; and
a reception device that includes the optical detection device described in claim that detects light having a wavelength of 400 nm or more and 1500 nm or less, and that demodulates the detected light.
